(19) United States
(12) Patent Application Publication
(10) Pub. No.: US 2025/0096011 A1
(43) Pub. Date: Mar. 20, 2025

(54) SEMICONDUCTOR MANUFACTURING APPARATUS AND METHOD OF MANUFACTURING A SEMICONDUCTOR DEVICE

(71) Applicant: Kioxia Corporation, Tokyo (JP)

(72) Inventors: Takahiro KAWATA, Yokkaichi Mie (JP); Shinsuke KIMURA, Yokkaichi Mie (JP); Satoshi NAKAOKA, Yokkaichi Mie (JP); Satoru OHGATA, Yokkaichi Mie (JP)

(21) Appl. No.: 18/821,893

(22) Filed: Aug. 30, 2024

(30) Foreign Application Priority Data
Sep. 15, 2023 (JP) 2023-150240

(51) Int. Cl. H01L 21/67

(52) U.S. Cl. CPC H01L 21/67034

(57) ABSTRACT

A semiconductor manufacturing apparatus includes a chamber, an opening/closing portion, and a pressure control circuit. The chamber includes first and second portions, both of which are capable of accommodating a wafer. The opening/closing portion is provided between the first portion and the second portion, and is movable to open and close a space between the first and second portions. The pressure control circuit is configured to control a pressure difference between the first portion and the second portion.

### CROSS-REFERENCE TO RELATED APPLICATION(S)

This application is based upon and claims the benefit of priority from Japanese Patent Application No. 2023-150240, filed Sep. 15, 2023, the entire contents of which are incorporated herein by reference.

### FIELD

Embodiments described herein relate generally to a semiconductor manufacturing apparatus and a method of manufacturing a semiconductor device.

### BACKGROUND

A drying treatment using a batch-type silylation treatment apparatus may be performed. When cleaning is performed with isopropyl alcohol (IPA) after the silylation treatment, dust in the chamber after the silylation treatment may adhere to the wafer.

### DESCRIPTION OF THE DRAWINGS

FIG. 1 is a diagram showing an example of a configuration of a semiconductor manufacturing apparatus according to a first embodiment.

FIG. 2 is a top view showing an example of a configuration of the semiconductor manufacturing apparatus according to the first embodiment.

FIGS. 3A to 3E are diagrams showing an example of a method of manufacturing a semiconductor device according to the first embodiment.

FIG. 4A is a diagram showing an example of the method of manufacturing a semiconductor device according to the first embodiment.

FIG. 4B is a diagram showing an example of the method of manufacturing a semiconductor device following FIG. 4A.

FIG. 4C is a diagram showing an example of the manufacturing method of manufacturing a semiconductor device following FIG. 4B.

FIG. 4D is a diagram showing an example of the manufacturing method of manufacturing a semiconductor device following FIG. 4C.

FIG. 5 is a diagram showing an example of a manufacturing method of manufacturing a semiconductor device according to a comparative example.

FIG. 6 is a diagram showing an example of a configuration of an opening/closing portion of a second embodiment.

FIG. 7 is a diagram showing an example of adjustment of an opening ratio of the opening/closing portion of the second embodiment.

FIG. 8A is a diagram showing an example of a manufacturing method of manufacturing a semiconductor device according to the second embodiment.

FIG. 8B is a diagram showing an example of the manufacturing method of manufacturing a semiconductor device following FIG. 8A.

FIG. 8C is a diagram showing an example of the manufacturing method of manufacturing a semiconductor device following FIG. 8B.

FIG. 8D is a diagram showing an example of the manufacturing method of manufacturing a semiconductor device following FIG. 8C.

FIG. 8E is a diagram showing an example of the manufacturing method of manufacturing a semiconductor device following FIG. 8D.

FIG. 9 is a diagram showing an example of a configuration of an opening/closing portion of a third embodiment.

### DETAILED DESCRIPTION

Embodiments provide a semiconductor manufacturing apparatus and a method of manufacturing a semiconductor device capable of reducing adhesion of dust to a wafer.

In general, according to one embodiment, a semiconductor manufacturing apparatus includes a chamber, an opening/closing portion, and a pressure control circuit. The chamber includes first and second portions, both of which are capable of accommodating a wafer. The opening/closing portion is provided between the first portion and the second portion, and is movable to open and close a space between the first and second portions. The pressure control circuit is configured to control a pressure difference between the first portion and the second portion.

Hereinafter, embodiments of the present disclosure will be described with reference to the drawings. The present embodiment does not limit the present disclosure. The drawings are schematic or conceptual, and the ratio or the like of each part is not necessarily the same as the actual one. In the specification and drawings, the same reference numerals are given to the same elements as those described above with respect to the previous drawings, and detailed description thereof will be omitted as appropriate.

### First Embodiment

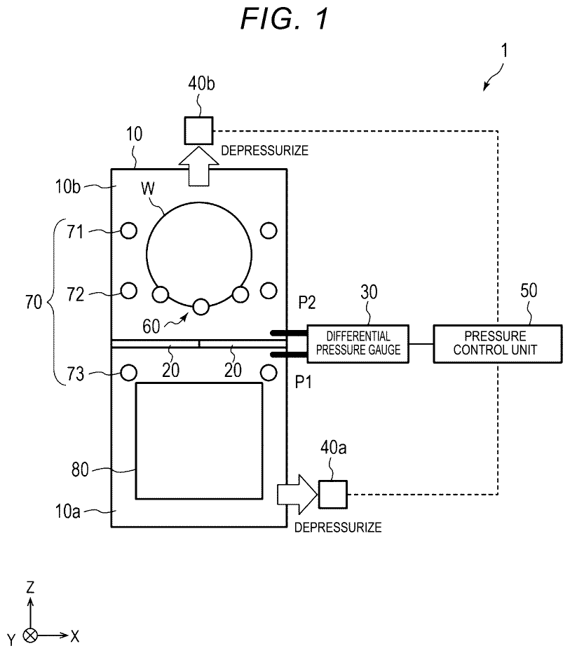

FIG. 1 is a diagram showing an example of a configuration of a semiconductor manufacturing apparatus 1 according to a first embodiment.

The semiconductor manufacturing apparatus 1 includes a chamber 10, an opening/closing portion 20, a differential pressure gauge 30, a depressurization unit 40, a pressure control unit 50, a wafer holding unit 60, a supply unit 70, and a treatment tank 80.

The chamber 10 accommodates a wafer W. The wafer W accommodated in the chamber 10 is subjected to cleaning or the like. The chamber 10 can accommodate a plurality of wafers W. Therefore, the semiconductor manufacturing apparatus 1 is a batch-type apparatus. The chamber 10 includes an accommodating portion 10a and an accommodating portion 10b that are separated by the opening/closing portion 20.

The opening/closing portion 20 divides the inside of the chamber 10 into the accommodating portion 10a on the lower part side and the accommodating portion 10b on the upper part side. That is, the opening/closing portion 20 is provided between the accommodating portion 10a and the accommodating portion 10b. The opening/closing portion 20 is provided, for example, in the vicinity of the center of the chamber 10 in the Z direction. By closing the opening/closing portion 20, the inside of the chamber 10 is separated into the accommodating portions 10a and 10b so that they are isolated from each other. That is, when the opening/closing portion 20 is open, the accommodating portions 10a and 10b are connected, i.e., in fluid communication, with each other. The opening/closing portion 20 opens and closes a space between the accommodating portion 10a and the accommodating portion 10b such that the wafer W can move between the accommodating portion 10a and the accommodating portion 10b in the chamber 10. The opening/closing portion 20 is, for example, an openable/closable shutter.

The opening/closing portion 20 includes, for example, two plate-shaped members that are movable in an XY plane. The opening/closing of the opening/closing portion 20 is performed, for example, by moving (e.g., sliding) the plate-shaped member in the X direction. The opening/closing portion 20 is closed, for example, by moving the plate-shaped member on the left side to the right and moving the plate-shaped member on the right side to the left. The opening/closing portion 20 opens, for example, by moving the plate-shaped member on the left side to the left and moving the plate-shaped member on the right side to the right. In the present embodiment, as shown in FIG. 1, the accommodating portion 10a and the accommodating portion 10b are separated from each other in a state in which the right end of the plate-shaped member on the left side and the left end of the plate-shaped member on the right side are in contact with each other in the vicinity of the center of the chamber 10 in the X axis. It should be noted that the opening/closing portion 20 may include a single plate-shaped member that is moved to the left or right to open or close opening/closing portion 20.

It should be noted that FIG. 1 shows a Z direction in which the accommodating portion 10a and the accommodating portion 10b are arranged, and an X direction and a Y direction that are perpendicular to the Z direction and perpendicular to each other. In the present specification, a +Z direction is regarded as an upward direction, and a −Z direction is regarded as a downward direction. The −Z direction, however, may or may not coincide with the direction of gravity.

The differential pressure gauge 30 is a sensor that measures a pressure difference between a pressure P1 of the accommodating portion 10a and a pressure P2 of the accommodating portion 10b.

The depressurization unit 40 depressurizes the inside of the chamber 10. The depressurization unit 40 depressurizes the inside of the chamber 10, for example, by evacuating the gas from the chamber 10 through an evacuation port (not shown). The depressurization unit 40 is, for example, a vacuum pump. The depressurization unit 40 includes a depressurization unit 40a that depressurizes the accommodating portion 10a and a depressurization unit 40b that depressurizes the accommodating portion 10b.

The pressure control unit 50 is a control circuit that controls the pressure of each of the accommodating portions 10a and 10b. The control circuit includes a processor that is programmed with firmware to perform the functions of the control circuit described herein. More specifically, the pressure control unit 50 controls each of the depressurization units 40a and 40b to control the pressure of each of the accommodating portions 10a and 10b. The pressure control unit 50 controls the pressures of the accommodating portions 10a and 10b based on the pressure difference measured by the differential pressure gauge 30.

The wafer holding unit 60 holds the wafer W. The wafer holding unit 60 moves the wafer W between the accommodating portion 10a and the accommodating portion 10b while holding the wafer W. In the present embodiment, the wafer holding unit 60 is, for example, three cylindrical members extending in the Y direction and movable in the Z direction.

The supply unit 70 is a gas supply apparatus that includes a nozzle connected to a gas supply and supplies a gas or the like into the chamber 10. The supply unit 70 includes supply units 71, 72, and 73. The supply units 71, 72, and 73 are provided, for example, on the left and right so that the wafer W is interposed. In addition, the supply unit 73 is provided, for example, above the treatment tank 80.

The supply unit 71 is provided in the accommodating portion 10b. The supply unit 71 can supply, for example, an inert gas. The inert gas is, for example, an N₂ gas.

The supply unit 72 is provided in the accommodating portion 10b. The supply unit 72 can supply, for example, a mist-like organic solvent. The organic solvent is, for example, alcohol. The alcohol is, for example, isopropyl alcohol (IPA).

The supply unit 73 is provided in the accommodating portion 10a. The supply unit 73 can supply, for example, a mist-like silylating agent and/or an N₂ gas (inert gas). The silylating agent is a chemical for achieving silylation. The silylation means replacing active hydrogen in a substance with a silyl group (—SiR₃). The silylating agent includes silicon (Si).

The treatment tank 80 stores pure water. The treatment tank 80 is provided in the accommodating portion 10a.

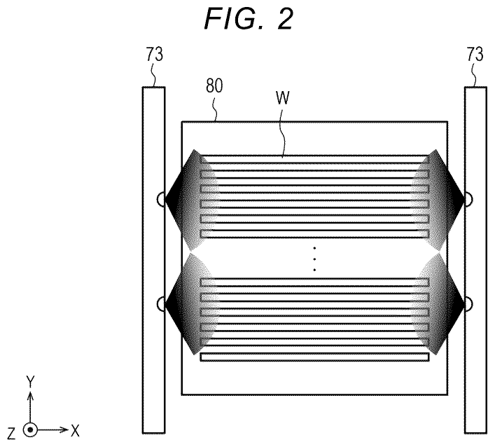

FIG. 2 is a top view showing an example of a configuration of the semiconductor manufacturing apparatus 1 according to the first embodiment. FIG. 2 shows the disposition of the chamber 10, the supply unit 73, and the wafer W as viewed from the Z direction during the silylation treatment.

The supply unit 73 has a pipe that extends in the Y direction. In the example shown in FIG. 2, the two supply units 73 are shown. The mist-like silylating agent and/or the N₂ gas pass through the inside of the pipe and are supplied into the treatment tank 80 from the hole provided in the pipe. It should be noted that the configurations of the supply units 71 and 72 are the same as that of the supply unit 73.

Next, the operation of the silylation treatment will be described.

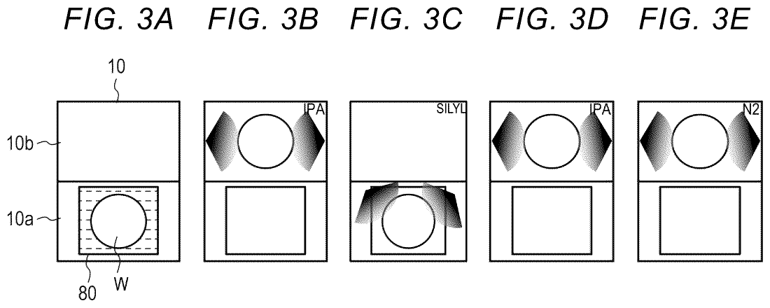

FIGS. 3A to 3E are diagrams showing an example of a method of manufacturing a semiconductor device according to the first embodiment. The treatment is performed sequentially from the left to the right in FIGS. 3A to 3E.

First, as shown in FIG. 3A, the wafer W is immersed in the pure water inside the treatment tank 80.

Next, as shown in FIG. 3B, the wafer W is moved to the accommodating portion 10b, and the wafer W is cleaned with the IPA. As a result, the pure water on the wafer W is replaced with the IPA.

Next, as shown in FIG. 3C, the wafer W is moved to the accommodating portion 10a, and the wafer W is subjected to a silylation treatment.

Next, as shown in FIG. 3D, the wafer W is moved to the accommodating portion 10b, and the wafer W is cleaned with the IPA.

Next, as shown in FIG. 3E, the wafer W is subjected to a drying treatment. The N₂ gas is supplied to the inside of the chamber 10. Thereafter, the wafer W is carried out from the chamber 10.

Next, the pressure control via the pressure control unit 50 will be described in detail.

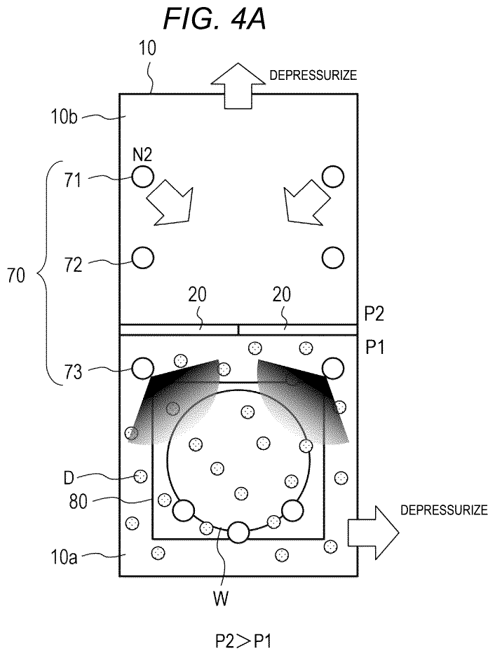

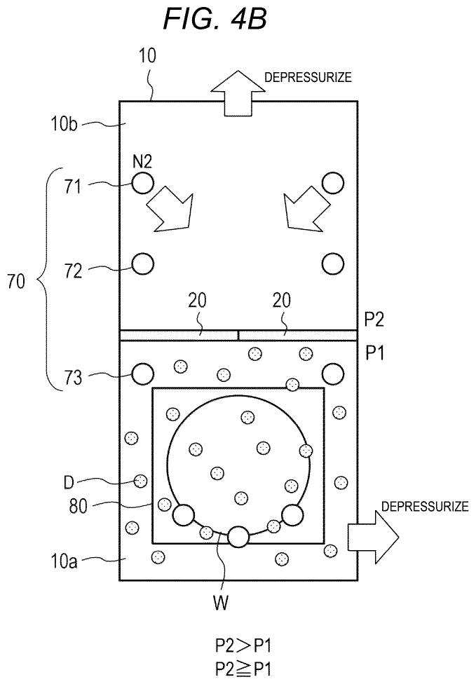

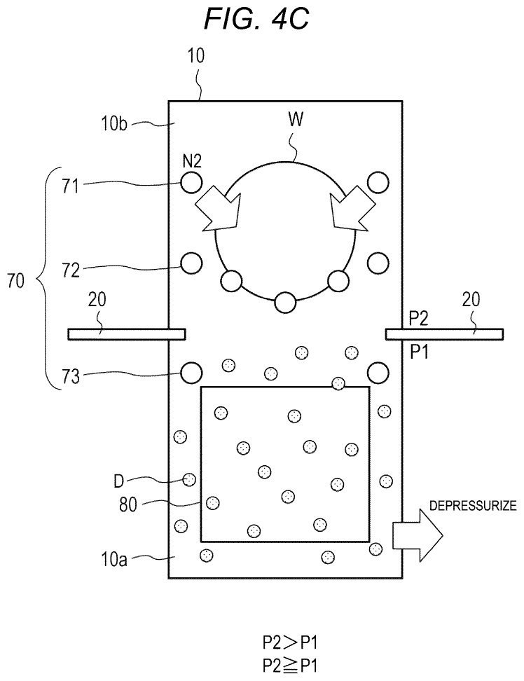

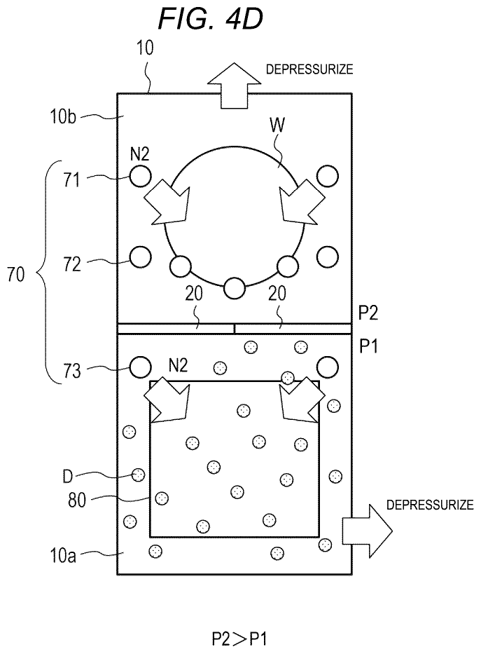

FIGS. 4A to 4D are diagrams showing an example of the method of manufacturing a semiconductor device according to the first embodiment. FIGS. 4A to 4D correspond to the step of the silylation treatment shown in FIG. 3C.

First, as shown in FIG. 4A, the wafer W is subjected to a silylation treatment. That is, the supply unit 73 supplies the silylating agent to the wafer W accommodated in the accommodating portion 10a. In addition, the supply unit 73 supplies the silylating agent toward a direction of the treatment tank 80 so that the silylating agent is not wound around the entire chamber 10. The silylating agent is supplied to the inside of the treatment tank 80 and the entire accommodating portion 10a on the outside of the treatment tank 80. For example, a remaining silylating agent that is not adhered to the wafer W when supplying the silylating agent or a silylating agent that reacts with the IPA on the wafer W forms dust D. The silylating agent may form the dust D, for example, by reacting with another silylating agent, not only by reacting with the IPA. The dust D is not limited to the dust generated by the silylation treatment. However, as compared with other treatments, in the silylation treatment, there is a tendency that a large amount of dust D is generated. Therefore, the present embodiment is suitable for use in a silylation treatment. The pressure control unit 50 performs the control such that the pressure P2 of the accommodating portion 10b is higher than the pressure P1 of the accommodating portion 10a at the timing shown in FIG. 4A.

In addition, the supply unit 71 supplies the N₂ gas to the accommodating portion 10b. The pressure P2 of the accommodating portion 10b may increase because of the supply of the N₂ gas.

Next, as shown in FIG. 4B, the pressures P1 and P2 of the accommodating portions 10a and 10b are adjusted after the silylation treatment is ended. More specifically, the depressurization unit 40 depressurizes each of the accommodating portions 10a and 10b. The pressure control unit 50 controls the pressure of each of the accommodating portions 10a and 10b such that the pressure P2 of the accommodating portion 10b is equal to or higher than the pressure P1 of the accommodating portion 10a (P2≥P1) at the timing shown in FIG. 4B.

Next, as shown in FIG. 4C, the opening/closing portion 20 is opened to move the wafer W. At the timing shown in FIG. 4C, the opening/closing portion 20 is opened while the pressures P1 and P2 of the accommodating portions 10a and 10b satisfy P2≥P1. The wafer holding unit 60 moves the wafer W from the accommodating portion 10b to the accommodating portion 10a.

Since the pressure P2 of the accommodating portion 10b is equal to or higher than the pressure P1 of the accommodating portion 10a, the dust D of the accommodating portion 10a can be prevented from moving to the accommodating portion 10b. In addition, the pressure control unit 50 may stop the depressurization unit 40b that depressurizes the accommodating portion 10b such that the dust D does not move to the accommodating portion 10b.

It should be noted that, the higher the pressure P2 is than the pressure P1, the easier it is to push out the dust D between the plurality of wafers W. Therefore, in the steps shown in FIGS. 4B and 4C, the pressures in the accommodating portions 10a and 10b may be controlled such that the pressure P2 of the accommodating portion 10b is higher than the pressure P1 of the accommodating portion 10a (P2>P1). Therefore, the opening/closing portion 20 is opened while the pressures P1 and P2 of the accommodating portions 10a and 10b satisfy P2>P1, and the wafer W is moved from the accommodating portion 10a to the accommodating portion 10b.

On the other hand, when the difference between the pressure P1 and the pressure P2 is large, a rapid airflow may be generated because of the pressure difference at the moment when the opening/closing portion 20 is opened. Because of the generation of the rapid airflow, the dust D may move to the accommodating portion 10b. Therefore, the pressure P2 of the accommodating portion 10b may be substantially the same as the pressure P1 of the accommodating portion 10a. Therefore, in the steps shown in FIGS. 4B and 4C, the pressure control unit 50 may control the pressures of the accommodating portion 10a and the accommodating portion 10b such that the pressure P2 of the accommodating portion 10b is substantially the same as the pressure P1 of the accommodating portion 10a.

Next, as shown in FIG. 4D, the opening/closing portion 20 is closed to replace the gas (atmosphere) inside the accommodating portion 10a with the N₂ gas. That is, the opening/closing portion 20 divides the accommodating portion 10a and the accommodating portion 10b. The depressurization unit 40a evacuates the gas inside the accommodating portion 10a, and the supply unit 73 supplies the N₂ gas. The depressurization unit 40b evacuates the gas inside the accommodating portion 10b, and the supply unit 71 supplies the N₂ gas. As a result, it is possible to discharge the gas containing the dust D inside the accommodating portion 10a and the accommodating portion 10b. The pressure control unit 50 performs the control such that the pressure P2 of the accommodating portion 10b is higher than the pressure P1 of the accommodating portion 10a at the timing shown in FIG. 4D.

As described above, according to the first embodiment, the opening/closing portion 20 divides the inside of the chamber 10 into the accommodating portion 10a on the lower part side and the accommodating portion 10b on the upper part side. The opening/closing portion 20 opens and closes the space between the accommodating portion 10a and the accommodating portion 10b such that the wafer W can move between the accommodating portion 10a and the accommodating portion 10b in the chamber 10. The pressure control unit 50 controls the pressure of each of the accommodating portion 10a and the accommodating portion 10b. As a result, after the silylation treatment in the accommodating portion 10a, the wafer W can be relocated to the region with less dust D (the accommodating portion 10b) for protection. As a result, the adhesion of the dust D to the wafer W can be reduced.

It should be noted that, instead of the differential pressure gauge 30, two sensors that respectively measure the pressure of the accommodating portion 10a and the pressure of the accommodating portion 10b may be provided. In this case, for example, the pressure control unit 50 calculates a pressure difference from the measurement results of the two sensors, and controls the pressure of each of the accommodating portions 10a and 10b based on the calculated pressure difference. The sensor is, for example, a pressure gauge.

### COMPARATIVE EXAMPLE

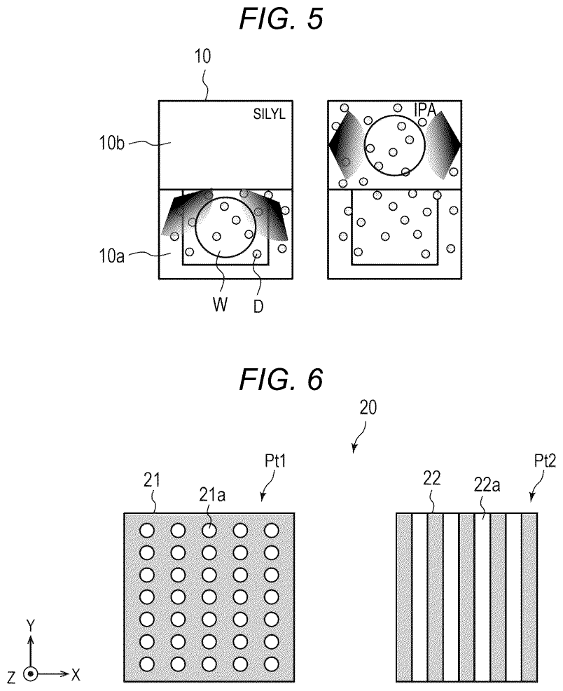

FIG. 5 is a diagram showing an example of a method of manufacturing a semiconductor device according to a comparative example. FIG. 5 shows the supply of the silylating agent and the supply of the IPA, which correspond to the steps shown in FIGS. 3C and 3D, respectively.

When the pressure control of the accommodating portions 10a and 10b is not performed, the dust D inside the chamber 10 may adhere to the wafer W after the silylation treatment, and the wafer W may be contaminated. In addition, the dust D may be wound up by the jetting of the gas or the chemical liquid from the supply unit 70, and the inside of the chamber 10 may be contaminated.

On the other hand, in the first embodiment, the dust D can be prevented from entering the predetermined region (e.g., the accommodating portion 10b) by independently controlling the pressure P1 of the accommodating portion 10a and the pressure P2 of the accommodating portion 10b. As a result, after the silylation treatment in the accommodating portion 10a, the wafer W can be relocated to the region where the dust D is present in relatively small amounts (i.e., the accommodating portion 10b) for protection, and the adhesion of the dust D to the wafer W can be reduced.

It should be noted that, the plate-shaped member of the opening/closing portion 20 is moved in the X direction in the present embodiment, but may be moved in the Y direction in addition to the X direction. For example, when the number of the wafers W accommodated in the chamber 10 is small, there is more space in which the wafer W is not accommodated as compared with a case where the maximum number of the wafers W accommodatable in the chamber 10 is accommodated. The plate-shaped member may be moved such that a position corresponding to the space not accommodating the wafer W is opened first. As a result, it is possible to reduce the dust D adhering to the wafer W by allowing the gas inside the accommodating portion 10a containing the dust D to flow in the space not accommodating the wafer W. That is, the movement of the plate-shaped member may be controlled in accordance with the positions of the plurality of wafers W in the chamber 10. In addition, the positions of the plurality of wafers W may be changed in accordance with the movement of the plate-shaped member.

### Second Embodiment

FIG. 6 is a diagram showing an example of a configuration of the opening/closing portion 20 of a second embodiment. In the second embodiment, the configuration of the opening/closing portion 20 is different from that in the first embodiment.

The opening/closing portion 20 includes a plate-shaped member 21 and a plate-shaped member 22.

The plate-shaped member 21 has a plurality of circular through-holes 21a of a pattern Pt1. The plate-shaped member 21 is, for example, a punched shutter. The shape and arrangement of the through-holes 21a are not limited to the example shown in FIG. 6.

The plate-shaped member 22 overlaps with the plate-shaped member 21 in the Z direction. The plate-shaped member 22 is movable in the XY plane direction with respect to the plate-shaped member 21. The plate-shaped member 22 has a plurality of rectangular through-holes 22a of a pattern Pt2. The pattern Pt2 has a pectinate shape (vertical stripe shape). The plate-shaped member 22 is, for example, a jig that can close the through-holes 21a of the plate-shaped member 21.

Therefore, the opening ratio of the plurality of through-holes 21a of the plate-shaped member 21 can be adjusted in addition to the opening/closing of the two plate-shaped members.

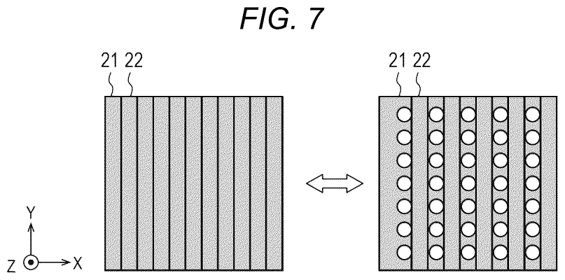

FIG. 7 is a diagram showing an example of adjustment of an opening ratio of the opening/closing portion 20 according to the second embodiment.

Since one of the plate-shaped members 21 and 22 moves with respect to the other in the XY plane direction, the degree of overlapping between the through-hole 21a and the rectangular through-hole 22a is changed, so that the opening ratio of the opening/closing portion 20 is adjustable.

The left side of FIG. 7 shows a case where the through-hole 21a and the rectangular through-hole 22a do not overlap with each other as viewed from the Z direction. In this case, the opening/closing portion 20 is in a closed state (sealed state).

The right side of FIG. 7 shows a case where the through-hole 21a and the rectangular through-hole 22a overlap with each other as viewed from the Z direction. In this case, the opening/closing portion 20 is in an open state. That is, in FIG. 4B and FIG. 4C of the silylation treatment, the gas can pass through the opening/closing portion 20 via the pressure difference. Therefore, the open state is also a state in which the airflow from the accommodating portion 10b to the accommodating portion 10a can be generated (downflow state).

The closed state and the open state can be switched by changing the relative positions of the plate-shaped member 21 and the plate-shaped member 22 as viewed from the Z direction (shifting the positional relationship between the plate-shaped members 21 and 22). In addition, the opening/closing portion 20 can also be adjusted to an opening ratio of a state between the closed state and the open state (for example, a half-open state). That is, the opening ratio of the opening/closing portion 20 can be adjusted.

It should be noted that, when the opening/closing portion 20 is opened, both the two plate-shaped members 21 and 22 move (e.g., slide) in the same manner as the plate-shaped member according to the first embodiment.

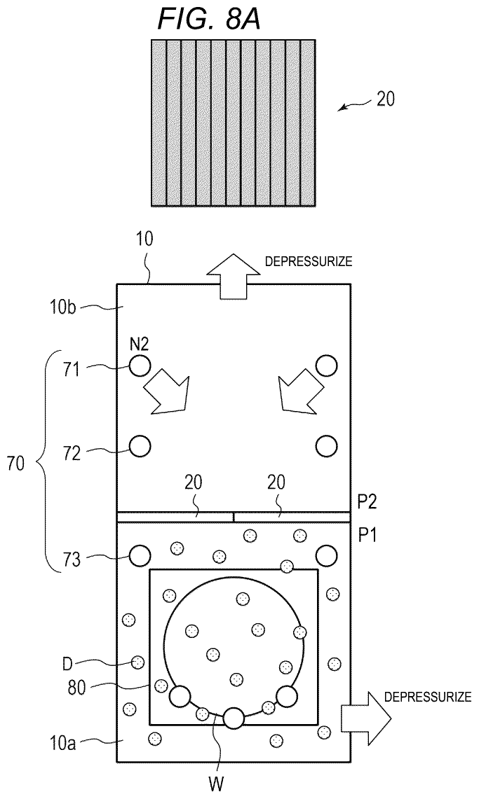

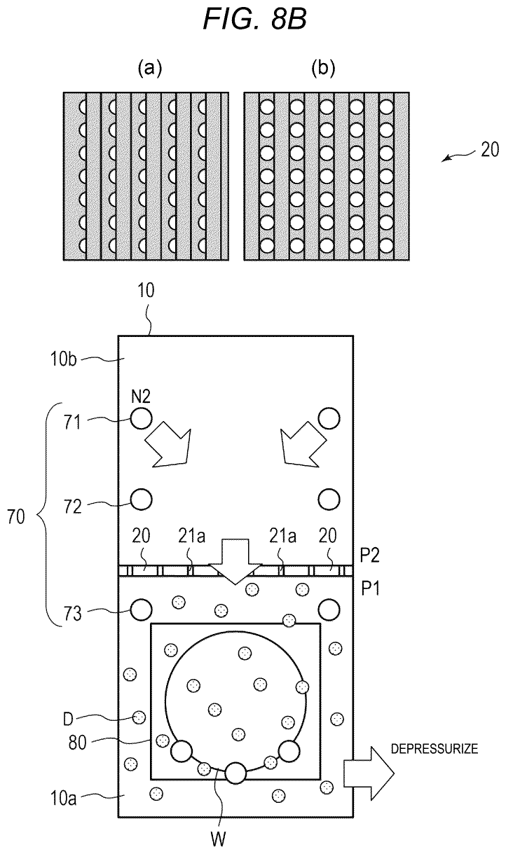

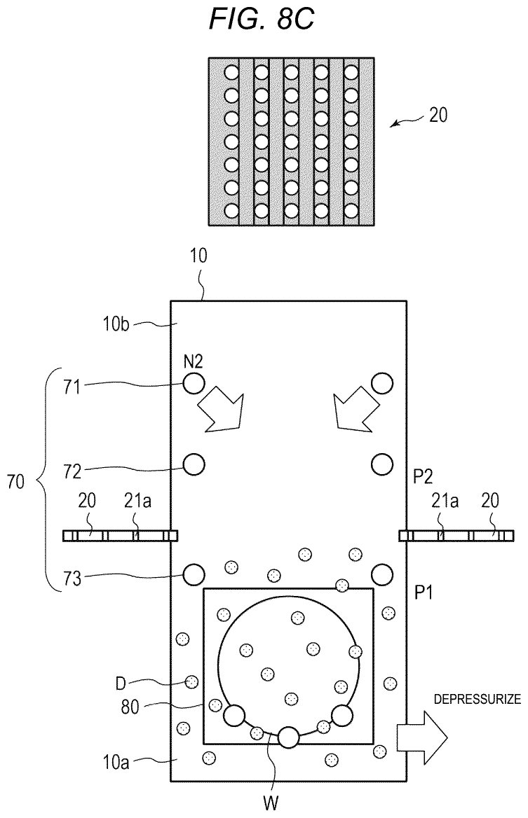

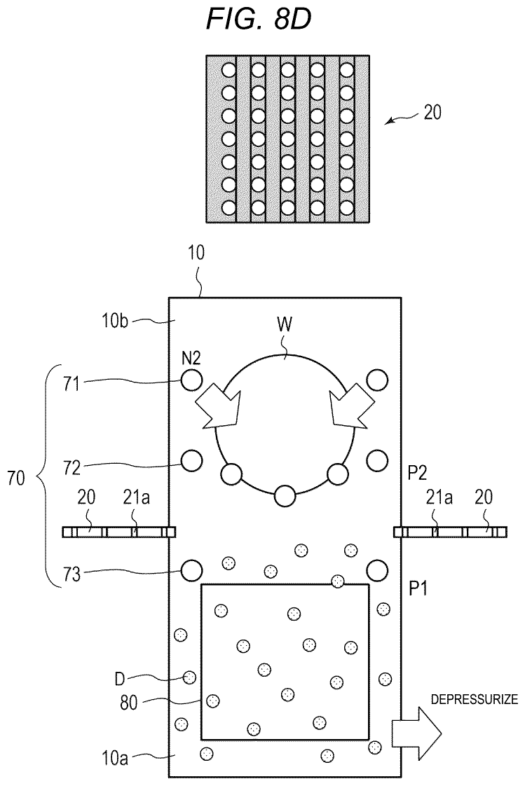

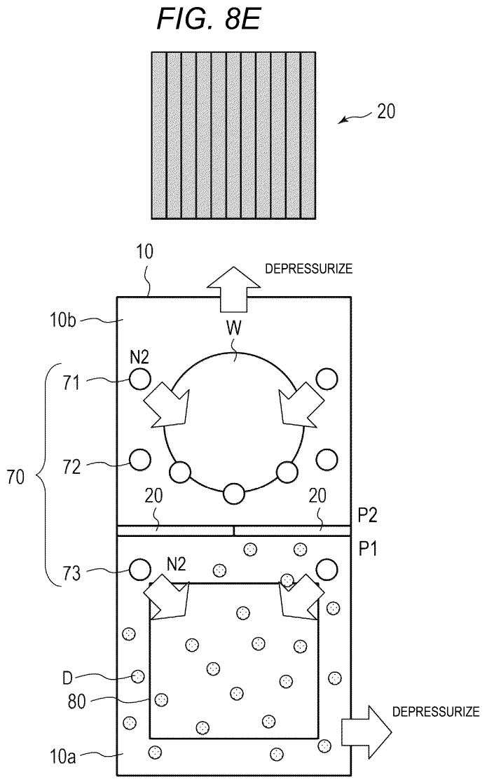

FIGS. 8A to 8E are diagrams showing examples of the method of manufacturing a semiconductor device according to the second embodiment. The upper side of FIG. 8A shows an opening state (opening ratio) of the opening/closing portion 20.

First, FIG. 8A shows the end of the silylation treatment. The step shown in FIG. 8A corresponds to the step shown in FIG. 4B of the first embodiment. At the timing shown in FIG. 8A, the opening/closing portion 20 is closed. That is, the through-hole 21a and the rectangular through-hole 22a do not overlap with each other (in the sealed state), and the accommodating portion 10a and the accommodating portion 10b are separated from each other by the opening/closing portion 20.

In addition, the accommodating portions 10a and 10b are depressurized. The accommodating portion 10b is supplied with N₂ gas.

Next, as shown in FIG. 8B, the opening state of the opening/closing portion 20 is adjusted such that the opening ratio of the opening/closing portion 20 is gradually increased. That is, the opening/closing portion 20 transitions from the closed state to the half-open state (see part (a) of FIG. 8B), and then to the open state (see part (b) of FIG. 8B). At the timing shown in FIG. 8B, the opening/closing portion 20 is gradually opened. That is, the opening/closing portion 20 gradually shifts the positions of the plate-shaped members 21 and 22 from each other to gradually increase the opening ratio. By gradually opening the opening/closing portion 20, the generation of the rapid airflow can be reduced and the winding up of the dust D can be reduced.

In addition, in the step shown in FIG. 8B, the depressurization of the accommodating portion 10b is stopped, and the N₂ gas is supplied. Therefore, the pressure P2 of the accommodating portion 10b is higher than the pressure P1 of the accommodating portion 10a. As a result, the opening/closing portion 20 is in a state in which the airflow from the accommodating portion 10b to the accommodating portion 10a can be generated (downflow state). That is, the through-hole 21a and the rectangular through-hole 22a overlap with each other (in the open state), and the accommodating portion 10a and the accommodating portion 10b are separated from each other by the opening/closing portion 20. Therefore, the dust D in the vicinity of the opening/closing portion 20 can be pushed downward. As a result, the winding up of the dust D when the opening/closing portion 20 is opened that may occur in FIG. 4B and FIG. 4C, can be further reduced.

Next, as shown in FIG. 8C, the opening/closing portion 20 is opened. The opening/closing portion 20 moves both the two plate-shaped members 21 and 22. That is, the through-hole 21a and the rectangular through-hole 22a overlap with each other (in the open state), and the accommodating portion 10a and the accommodating portion 10b are not separated from each other by the opening/closing portion 20.

Next, as shown in FIG. 8D, the wafer W is moved from the accommodating portion 10a to the accommodating portion 10b.

Next, as shown in FIG. 8E, the opening/closing portion 20 is closed. The step shown in FIG. 8E corresponds to the step shown in FIG. 4D of the first embodiment. At the timing shown in FIG. 8E, the opening/closing portion 20 is in the closed state. That is, the through-hole 21a and the rectangular through-hole 22a do not overlap with each other (in the sealed state), and the accommodating portion 10a and the accommodating portion 10b are separated from each other by the opening/closing portion 20.

In the second embodiment, in the step shown in FIG. 8B, the opening ratio of the opening/closing portion 20 gradually increases. As a result, the generation of the rapid airflow can be reduced even when the pressure P1 of the accommodating portion 10a is higher than the pressure P2 of the accommodating portion 10b.

In addition, it is preferable that the through-holes 21a are provided substantially uniformly over substantially the entire XY plane of the plate-shaped member. As a result, the rectilinearity of the airflow in the open state (downflow state) can be improved.

The configuration of the opening/closing portion 20 may be changed as in the second embodiment. The semiconductor device according to the second embodiment can obtain the same effects as those of the semiconductor device according to the first embodiment.

### Third Embodiment

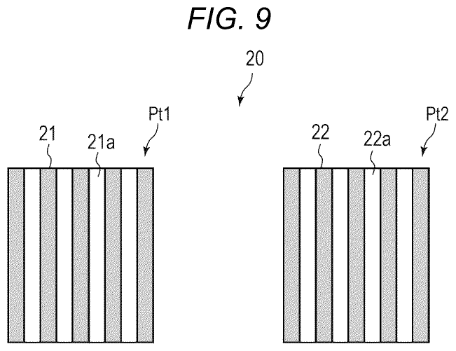

FIG. 9 is a diagram showing an example of a configuration of the opening/closing portion 20 of a third embodiment. The third embodiment is different from the second embodiment in that the patterns Pt1 and Pt2 of the plate-shaped member 21 and the plate-shaped member 22 are the same.

The patterns Pt1 and Pt2 are the same. As a result, the manufacturing cost can be reduced.

The pattern Pt1 shown in FIG. 9 is, for example, a pectinate shape as the pattern Pt2 of the second embodiment described with reference to FIG. 6.

The semiconductor device according to the third embodiment can obtain the same effects as those of the semiconductor device according to the second embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor manufacturing apparatus comprising:
a chamber that includes first and second portions, both of which are capable of accommodating a wafer;
an opening/closing portion that is provided between the first portion and the second portion and is movable to open and close a space between the first and second portions; and
a control circuit configured to control a pressure difference between the first portion and the second portion.

2. The semiconductor manufacturing apparatus according to claim 1,
wherein the control circuit is configured to control the pressure difference, such that the pressure of the second portion is equal to or higher than the pressure of the first portion.

3. The semiconductor manufacturing apparatus according to claim 1, further comprising:
a sensor configured to measure the pressure difference,
wherein the control circuit is configured to control the pressure of each of the first portion and the second portion based on the pressure difference measured by the sensor.

4. The semiconductor manufacturing apparatus according to claim 1, further comprising:
a first sensor configured to measure the pressure of the first portion and a second sensor configured to measure the pressure of the second portion,
wherein the control circuit is configured to calculate the pressure difference based on the pressures measured by the first and second sensors and to control the pressure of one or both of the first portion and the second portion based on the calculated pressure difference.

5. The semiconductor manufacturing apparatus according to claim 1, further comprising:
a first pump controlled by the control circuit to depressurize the first portion; and
a second pump controlled by the control circuit to depressurize the second portion.

6. The semiconductor manufacturing apparatus according to claim 5, wherein each of the first and second pumps is a vacuum pump.

7. The semiconductor manufacturing apparatus according to claim 1,
wherein the opening/closing portion includes first and second plate-shaped members that are each movable in a direction substantially perpendicular to a first direction along which the first and second portions are arranged.

8. The semiconductor manufacturing apparatus according to claim 7, wherein the first and second plate-shaped members are each a solid plate-shaped member.

9. The semiconductor manufacturing apparatus according to claim 7, wherein
the first plate-shaped member includes a plurality of first through-holes of a first pattern, and
the second plate-shaped member includes a plurality of second through-holes of a second pattern, and is movable relative to the first plate-shaped member to partially or entirely seal the space between the first and second portions.

10. The semiconductor manufacturing apparatus according to claim 9, wherein the first pattern and the second pattern are identical.

11. The semiconductor manufacturing apparatus according to claim 9, wherein the first pattern is a pattern of circular through-holes and the second pattern is a pattern of rectangular through-holes.

12. The semiconductor manufacturing apparatus according to claim 1, further comprising:
a first gas supply structure that is provided in the first portion and is capable of supplying a silylating agent to the wafer; and
a second gas supply structure that is provided in the second accommodating portion and is capable of supplying alcohol to the wafer.

13. A method of manufacturing of a semiconductor device comprising:
accommodating the wafer in a first portion of a chamber that is sealed off from a second portion of the chamber by a movable shutter;
supplying a silylating agent to the wafer accommodated in the first portion while the first portion is sealed off from the second portion;
controlling the pressure difference between the first portion and a second portion of the chamber such that the pressure of the second portion is equal to or higher than the pressure of the first portion;
moving the shutter to open a space between the first and second portions while the pressure of the second portion is maintained to be equal to or higher than the pressure of the first portion; and
moving the wafer through the space from the first portion to the second portion.

14. The method of manufacturing a semiconductor device according to claim 13, further comprising:
after moving the wafer from the first portion to the second portion, moving the shutter to close the space between the first and second portions; and
replacing a gas inside the second portion with an inert gas.

15. The method of manufacturing a semiconductor device according to claim 13, wherein the shutter is moved to open the space between the first and second portions while the pressure difference is zero.

16. The method of manufacturing a semiconductor device according to claim 13, wherein the shutter is moved to open the space between the first and second portions while the pressure of the second portion is higher than the pressure of the first portion.

17. The method of manufacturing a semiconductor device according to claim 13, wherein the shutter includes first and second plate-shaped members that are moved in opposite directions to open the space between the first and second portions.

18. The method of manufacturing a semiconductor device according to claim 17, wherein the first and second plate-shaped members are each a solid plate-shaped member.

19. The method of manufacturing a semiconductor device according to claim 17, wherein
the first plate-shaped member includes a plurality of first through-holes of a first pattern, and the second plate-shaped member includes a plurality of second through-holes of a second pattern, and
one of the first plate-shaped member and the second plate-shaped member is moved relative to the other to partially open the space between the first and second portions.

20. The method of manufacturing a semiconductor device according to claim 19, wherein the first pattern is a pattern of circular through-holes and the second pattern is a pattern of rectangular through-holes.
